(19) United States
(12) Patent Application Publication
(10) Pub. No.: US 2008/0262759 A1
(43) Pub. Date: Oct. 23, 2008

(54) System and method for testing information handling system components

(76) Inventors: Dustin D. Bosl, Weimar, TX (US); Glen B. McGonagle, Austin, TX (US); Milton O. Taveira, Round Rock, TX (US)

Correspondence Address: HAMILTON & TERRILE, LLP, P.O. BOX 203518, AUSTIN, TX, 78720, US

(21) Appl. No.: 11/736,723

(22) Filed: Apr. 18, 2007

(51) Int. Cl. G01R 31/00

(52) U.S. Cl. 702/58

(57) ABSTRACT

A system and method is disclosed for testing components used in the manufacture of information handling systems. In embodiments of the invention, a device-under-test (DUT) comprises a DUT identifier code. The DUT is operably coupled to a test bed. An information handling system is operable to use the identifier code to select and execute a predetermined test program to generate a plurality of test commands. A test bed interface is operable to receive the test commands and to generate a plurality of test control signals therefrom to perform a predetermined set of tests of said DUT.

### BACKGROUND OF THE INVENTION

1. Field of the Invention

The present invention relates in general to the field of information handling system manufacture, and more particularly to a system and method for automatically testing components used in the manufacture of information handling systems.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Testing the wide variety of components used in the manufacture of information handling systems presents a serious challenge. While the component manufacturers themselves may conduct tests, they often do so using widely variable methods, thereby creating inconsistent, non-repeatable manufacturing data and metric reports. Therefore, many manufacturers of information handling systems conduct their own tests of components to ensure consistency.

Historically, manufacturers have used customized test platforms that require the test components and interfaces to be reconfigured for each “device-under-test” (DUT). In some test environments, such as the testing of server blades, multiple power supplies are installed for each device under test when, in fact, a standard computer power supply could be used. Another problem with prior art testing systems relates to the inability to fully automate total network switching isolation for testing. Other examples of shortcomings of prior testing systems include the inability to easily change video graphics adapter (VGA) sources when there are multiple VGA connectors on a product to allow test and measurement of RGB (red-green-blue), horizontal synchronization, and vertical synchronization signals. In addition, AC wiring and fixtures are subject to quality issues and potential operator risks in most current testing systems. Prior art testing systems generally require the operator to rearrange wiring for each type of DUT.

As will be understood by those of skill in the art, the shortcomings of prior art testing systems has resulted in manufacturing inefficiencies. For example, when manufacturing orders suddenly increase, adding new testers to meet demand requires long lead times and re-engineering. Furthermore, there is currently no cost effective high current digital input/output (DIO) capability in prior art testing systems. In view of the foregoing, it is apparent there is a need for a universal test control box that can be easily adapted to serve in a multitude of testing environments.

### SUMMARY OF THE INVENTION

The present invention provides a universal test system that can be easily adapted to a wide variety of testing environments. Embodiments of the invention comprise a single enclosure comprising a plurality of testing components and a universal interface that can be programmed to perform tests on a wide variety of DUTs. The universal testing system of the present invention comprises test information handling system comprising a power supply, a plurality to data processing and data storage devices and a test bed interface comprising a plurality of solid state AC relays, a plurality of video multiplexers, a plurality of network interface (NIC) multiplexers and a plurality of analog-to-digital converters. The test bed interface comprises standard digital input/output (DIO) modules, as well as high-current capable DIO to handle devices that require high current sink levels.

The test information system provided by the present invention offers numerous advantages. The system can be used in administering fixtured and non-fixtured test solutions for all server, storage, and client products. In addition, the system comprises a power supply that provides all fixture-specific power needs. Furthermore, the DUT power is controlled using digital I/O controlled high current AC relays. Because of the connector and port configuration, the system can be quickly and easily swapped in a factory environment.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1a is a generalized diagram of a system for testing a component used in the manufacturing of information handling systems;

FIG. 1b is a block diagram of the test information handling system used in embodiments of the system and method of the present invention;

FIG. 2 is a block diagram of the functional components of the test bed interface used in embodiments of the present invention;

FIG. 3a is a perspective view of the front of a housing for the test system of the present invention;

FIG. 3b is a perspective view of the rear of a housing for the test system of the present invention; and

FIG. 4 is a flow diagram of processing steps for using the test system of the present invention.

### DETAILED DESCRIPTION

Embodiments of the system and method of the present invention provide significant improvements in the testing of components used to manufacture information handling systems. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

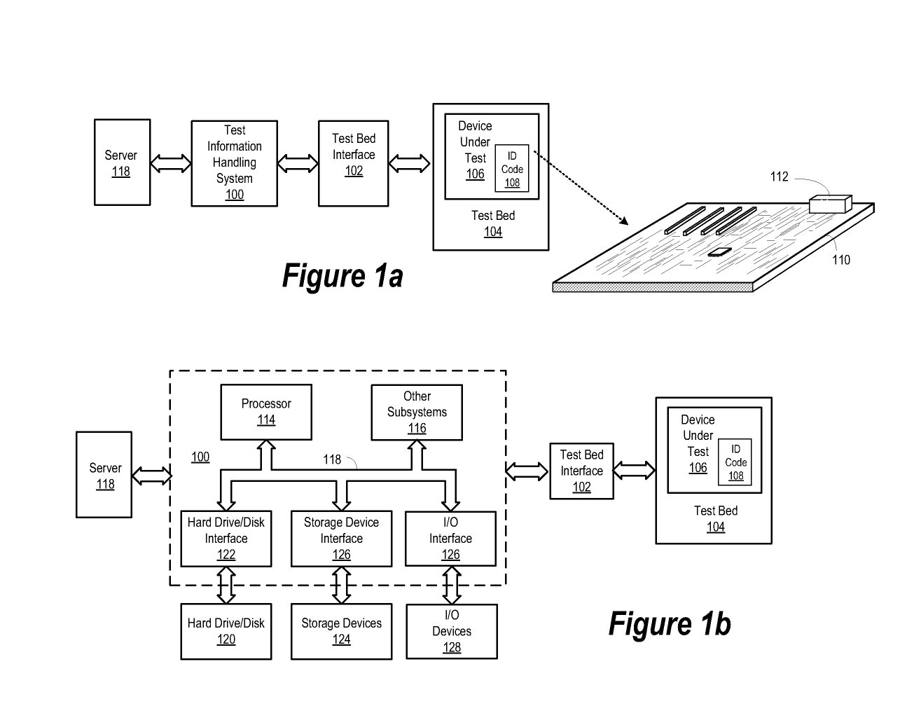

FIG. 1a is a general block diagram of a system for testing an information handling system in accordance with embodiments of the present invention. A test information handling system 100 is operably connected to a test bed interface 102, described in greater detail below, which is further connected to a test bed 104. The test bed comprises a plurality of electrical, mechanical and pneumatic components that are operable to subject the device-under-test (DUT) to a predetermined set of electrical, mechanical, and pneumatic tests. In various embodiments of the invention, the DUT comprises an identifier (IC) code that may be used to automatically configure the test information handling system 100 to perform a predetermined set of tests and to correlate the test results with a specific DUT. The test information handling system 100 is operably coupled to a server 106 and is operable to store test result data logs relating to the DUT at predetermined times during the testing sequence.

The DUT 106 test can be virtually any component of a circuit board that would be used in the manufacture of an information handling system. For example, the DUT may be a main system board 110 comprising a plurality of data processing components and a plurality of connectors and I/O ports, illustrated generally by reference numeral 112, that can be used to test proper operation of the components.

As shown in FIG. 1b, the test information handling system 100 comprises a processor 114 and various other subsystems 116 understood by those skilled in the art. Data is transferred between the various system components via various data buses illustrated generally by bus 118. Hard drive(s) 120 are controlled by a hard drive/disk interface 122. Likewise, data transfer between the system components and other storage devices 124 is controlled by storage device interface 126. The storage devices may include CD ROM drives, floppy drives, etc. In some embodiments of the invention, storage devices 124 may include a removable storage medium, such as a compact flash (CF) drive. An input/output (I/O) interface 126 controls the transfer of data between the various system components and a plurality of input/output (I/O) devices 128, known to those of skill in the art. As will be appreciated by those of skill in the art, most of the functional components described above can be implemented on a single circuit board, sometimes referred to as a “single board computer.”

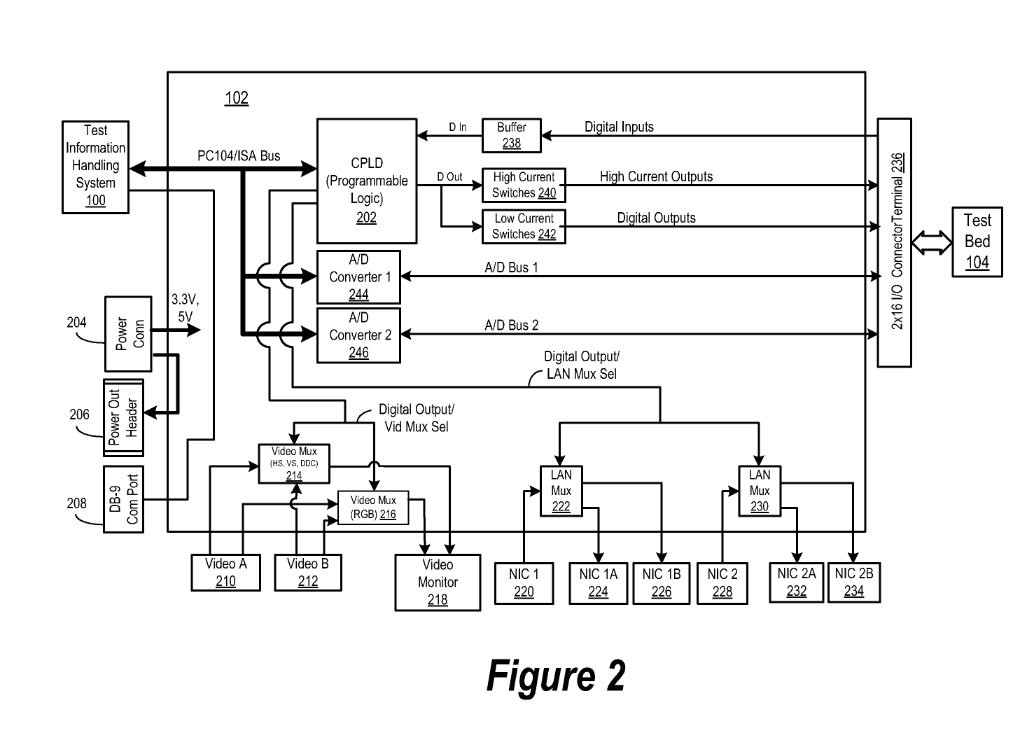

FIG. 2 is a block diagram showing the functional modules of the test bed interface 102. A CPLD (complex programmable logic device) module 202 is operable to control a plurality of data processing modules and to communicate with the test information handling system using a PC 104/ISA bus, although the features of the present invention can be implemented using a number of other industry standard buses. Electrical power for various modules is received via power connection port 204 and distributed via connections not explicitly shown. A power-out header 206 is also coupled to port 204 to provide electrical power for the DUT in some test configurations. Serial port connector 208 is a break-out connection to one of the serial ports in the test information handling system 100. Video data received via video ports 210 and 212 is provided as an input to video multiplexers 214 and 216. Horizontal sync, vertical sync and display data channel (DDC) data from each of the video ports 210, 212 is provided to multiplexer 214 and RGB data from each of the video ports is provided to multiplexer 216. The outputs of the multiplexers 214 and 216 are provided to a video monitor 218. Operation of the video multiplexers 214 and 216 are controlled by the CPLD 202.

The test bed interface 102 comprises two network interface (NIC) multiplexers that are operable to receive network protocol signals (e.g., Ethernet) and to extract plural network output signals therefrom. Network signals received at NIC 1 port 220 are processed by NIC multiplexer 222 to provide network output signals to network output ports 224 and 226. Likewise, network signals received at NIC 1 port 228 are processed by NIC multiplexer 230 to provide network output signals to network output ports 232 and 234. Operation of the LAN multiplexers 222, 230 are controlled by the CPLD 202.

Control signals and data signals are transmitted between the test bed interface and the test bed 104 via input/output connector 236. Digital input signals received from the test bed 104 via connector 236 are received in buffer 238 and transmitted to the CPLD 202 for processing. Digital control signals generated by the CPLD are provided to high-current switch module 240 to generate high-current outputs and to low-current switch module 242 to generate digital output that are provided to the test bed 104 via connector 236. The test bed interface 102 comprises two analog-to-digital (A/D) converters that are operable to process data transmitted between the CPLD and the test bed 104 via the connector 236. The various processing modules discussed hereinabove are capable of providing up to 13 external A/D channels 244, 246 (−10V to +10V) and 17 external digital I/O control channels.

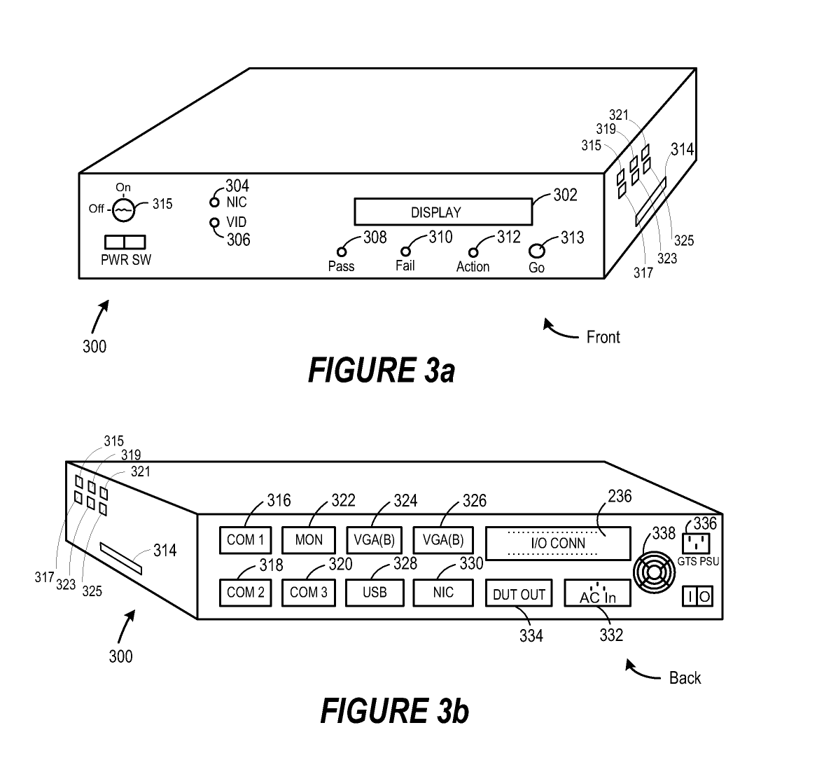

The functional components of the universal testing system 100 and the test bed interface 102 described hereinabove are contained in a housing 300 shown in FIGS. 3a and 3b. In various embodiments of the invention, one surface of the housing comprises a display 302 and a plurality of status indicator lights such as “NIC” indicator light 304, “video” indicator light 306, “pass” indicator light 308, “fail” indicator light 310, and an “action” indicator light 312. Each of these lights is used to display status information or to prompt a user to take a predetermined action, as discussed in greater detail below. A “Go” button 313, that is operably coupled to the processing logic and power systems described herein, is pushed by the user to initiate a testing sequence when prompted by a predetermined message on display 302, as described hereinbelow. A memory interface slot 314 is operable to receive a removable storage device, such as a compact flash card, that contains data and/or programs that are used to change the operating parameters of the universal test system.

A key-actuated switch 315 is connected to processing logic and power circuitry to enable the system to be started for debug operations. If a key is present in the switch, and the switch is in the “on” position, it cannot be removed. The system can then bypass the normal startup and can be powered-up to determine the status of debug operations.

The housing comprises a plurality of physical connectors that correspond to the various functional modules discussed in connection with FIG. 2. Two NIC input connectors 315 and 317 provide network data input signals to the NIC multiplexers discussed above. The outputs of the two NIC multiplexers are then provided via NIC connectors 319, 321, 323 and 325. Details relating to the rear of the universal test system housing 300 can be seen referring to FIG. 3b. The universal test system ports on the rear face of the housing include three com ports 316, 318, 320, a monitor input port 322, and first and second VGA output ports 324 and 326. It further comprises a USB port 328 and a network interface card port 330. Input power for the universal test system is provided by input port 322. Power for the unit under test is provided by DUT power output port 334. Likewise, power for the test system PSU is provided at port 336. A fan 338 is operable to provide cooling for the components inside the universal test system housing.

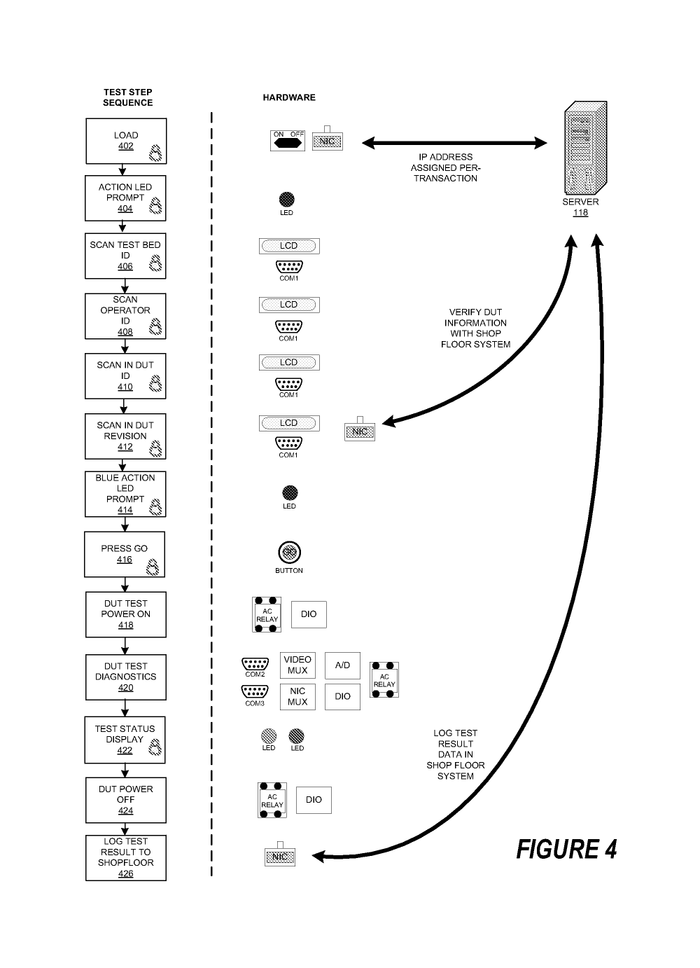

The features provided by the universal test system of the present invention allow the system to be used by operators having minimal training. FIG. 4 is an illustration of an exemplary sequence of processing steps implemented in embodiments of the present invention. The main hardware components of the test system are illustrated next to the dialog boxes for the various processing steps shown in FIG. 4. In step 402, the system is powered on by pressing the on/off switch and the NIC interface is used to obtain an initial test session IP address from the server. New IP addresses, which may be the same as the initial IP address, are obtained each time the system communicates with the server. In step 404, the “action” LED prompt is illuminated, prompting the operator to perform the sequence of steps in 406-412. In step 406, an appropriate scanner such as a laser scanner used to read barcodes, is used to scan the test bed ID. The LCD display prompts the user to scan the test bed ID and the result is obtained as a data input to COM1. In step 408, the LCD display provides a message prompting the operator to scan in the operator ID using an optical reading device and the resulting data input is received by the COM1 port. In step 410, the LCD displays a message prompting the user to scan in the DUT ID using the optical reader, and the resulting data is received by COM1. In step 412, the LCD displays a message prompting the operator to scan in the DUT revision using the optical reader, and the resulting data is provided as an input to COM1. At this point in the processing, the network connection between the NIC and the server is used to obtain verification that the DUT information is valid.

In the various embodiments of the invention described herein, the test information handling system 100 is operable to use various combinations of the test bed ID, the operator ID, the DUT ID and DUT revision information to select a predetermined test program to execute. The test program can be stored on various fixed storage devices in the test information handling system or it can be downloaded from a removable storage device or from the server 118 over a network connection.

In step 414, the action LED prompt is illuminated, thereby prompting the operator to press the “go” button in step 416 to initiate the test sequence. In step 418, the AC relay and the digital input/output modules power-on the device under test. In step 420, the DUT test diagnostics are performed using a test sequence provided by the removable storage device. The diagnostics are performed using the video multiplexers, the NIC multiplexers, the A/D converter, the digital input/output converter, the COM2 and COM3 ports, and the AC relay. In step 422, the test status is displayed using the video and network LEDs. In step 424, the AC relays and the digital input/output module are used to power down the DUT. Finally, in step 426, the data link between the network interface card and the server are used to log test results to the server. The test result log comprises the DUT identifier, an operator identifier and a test bed identifier.

The test information system provided by the present invention offers numerous advantages. The system can be used in administering fixtured and non-fixtured test solutions for all server, storage, and client products. In addition, the system comprises a power supply that provides all fixture-specific power needs (e.g., 12V, 5V, 3.3V, −12V). No additional power supplies are needed. The DUT power is controlled using digital I/O controlled high current AC relays. Because of the connector and port configuration, the system can be quickly and easily swapped in a factory environment.

Although the present invention has been described in detail, it should be understood that various changes, substitutions and alterations can be made hereto without departing from the spirit and scope of the invention as defined by the appended claims.

What is claimed is:

1. A system for testing information handling system components, the system comprising:
a test bed,
a device-under-test operably coupled to said test bed, said DUT comprising a DUT identifier code;
a test information handling system comprising data processing logic operable use said DUT identifier code to select and execute a test program to generate a plurality of test commands; and
a test bed interface operable to receive said test commands and to generate a plurality of test control signals to perform a predetermined set of tests of said DUT.

2. The system of claim 1, wherein the test program is transferred from a removable storage device to said test information handling system.

3. The system of claim 1, wherein data parameters regarding said DUT are transferred from a removable storage device to said test information handling system.

4. The system of claim 1, wherein the test bed interface comprises a plurality of video multiplexers operable to receive a plurality of input video data signals and to generate a predetermined set of output video data signals therefrom.

5. The system of claim 1, wherein said test bed interface comprises a plurality of local area network multiplexers operable to receive an input network protocol control signal and to generate a plurality of output network control signals therefrom.

6. The system of claim 1, wherein power provided to said DUT is controlled using digital I/O controlled high current AC relays.

7. The system of claim 1, wherein said test information handling system is operable to communicate with a manufacturing server to verify predetermined parameters for testing said DUT.

8. The system of claim 7, wherein said test information handling system is operable to receive revised parameters for testing said DUT.

9. The system of claim 1, wherein said test information handling system is operable to receive test result information from said test bed interface and to generate test result logs therefrom.

10. The system of claim 1, wherein said test result logs comprise said DUT identifier code and an operator identifier code.

11. A method for testing information handling system components, the method comprising:
coupling a device-under-test to a test bed, said DUT comprising a DUT identifier code;
using a test information handling system to select and execute a test program to generate a plurality of test commands, wherein said DUT identifier code is used by said test information handling system to select and execute said test program; and
using a test bed interface to receive said test commands and to generate a plurality of test control signals to perform a predetermined set of tests of said DUT.

12. The method of claim 11, further comprising: transferring the test program from a removable storage device to said test information handling system.

13. The method of claim 11, further comprising: transferring data parameters regarding said DUT from a removable storage device to said test information handling system.

14. The method of claim 11, wherein the test bed interface comprises a plurality of video multiplexers operable to receive a plurality of input video data signals and to generate a predetermined set of output video data signals therefrom.

15. The method of claim 11, wherein said test bed interface comprises a plurality of local area network multiplexers operable to receive an input network protocol control signal and to generate a plurality of predetermined output network control signals therefrom.

16. The method of claim 11, wherein power provided to said DUT is controlled using digital I/O controlled high current AC relays.

17. The method of claim 11, wherein said test information handling system is operable to communicate with a manufacturing server to verify predetermined parameters for testing said DUT.

18. The method of claim 17, wherein said test information handling system is operable to receive revised parameters for testing said DUT.

19. The method of claim 1, wherein said test information handling system is operable to receive test result information from said test bed interface and to generate test result logs therefrom.

20. The method of claim 19, wherein said test result logs comprise said DUT identifier code and an operator identifier code.
